(19) United States
(12) Patent Application Publication
(10) Pub. No.: US 2015/0062850 A1
(43) Pub. Date: Mar. 5, 2015

(54) PRINTED CIRCUIT BOARD

(71) Applicant: Samsung Electro-Mechanics Co., Ltd., Suwon (KR)

(72) Inventors: Cheol Ho CHOI, Hwasung (KR); Sung Jin Chun, Yeongi-gun (KR); Seok Kyu Lee, Yeongi-gun (KR); Dong Hoon Kim, Sungnam (KR)

(73) Assignee: Samsung Electro-Mechanics Co., Ltd., Suwon (KR)

(21) Appl. No.: 14/104,632

(22) Filed: Dec. 12, 2013

(30) Foreign Application Priority Data
Sep. 5, 2013 (KR) 10-2013-0106613

(51) Int. Cl. H05K 1/02

(52) U.S. Cl. CPC H05K 1/0271
USPC 361/764

(57) ABSTRACT

Disclosed herein is a printed circuit board of a build-up structure in which an insulating layer and a circuit layer are stacked on a core layer, the core layer including: an electronic chip cavity in which an electronic chip is accommodated; and a dummy chip cavity in which a dummy chip is accommodated to offset warpage by the electronic chip.

### CROSS REFERENCE(S) TO RELATED APPLICATIONS

This application claims the foreign priority benefit under 35 U.S.C. Section 119 of Korean Application No. 10-2013-0106613, entitled “Printed Circuit Board” filed on Sep. 5, 2013, which is hereby incorporated by reference in its entirety into this application.

### BACKGROUND OF THE INVENTION

1. Technical Field

The present invention relates to a printed circuit board, and more particularly, to a printed circuit board capable of suppressing warpage.

2. Description of the Related Art

Recently, as electronic devices become lighter, smaller, faster, multi-functional and highly functional, high density integration is increasingly required.

For high density integration, an electronic circuit board needs to be thinner, and thus a core which is a base for the electronic circuit board needs to be correspondingly thinner.

Currently, the process of manufacturing a printed circuit board includes forming circuit patterns on a core layer on which a copper foil is laminated, and laminating layers formed of resin on upper and lower surfaces thereof.

The circuit patterns on the core are formed by placing a mask over it to perform etching in a predetermined pattern.

Here, the layers in the core are electrically connected by forming a via hole using a CO2 laser drill or a mechanical drill and by forming a plating layer in a via hole for conduction between the layers.

In order to achieve high density integration and high performance, a pitch of wiring needs to be thinner. To this end, there was an attempt to substitute the physical property of the existing core material with glass fiber impregnated with resin.

If the core layer of the existing printed circuit board is thinner, however, many problems arise in the manufacturing process. In particular, when an electronic element is mounted on a completed printed circuit board, warpage is made due to stress between the electronic element and the board.

### RELATED ART DOCUMENT

### Patent Document

(Patent Document 1) Cited Reference: Korean Patent Laid-Open Publication No. 2002-0035939

### SUMMARY OF THE INVENTION

An object of the present invention is to provide a printed circuit board in which overall warpage of the board can be offset by incorporating a dummy chip to suppress warpage by an electronic chip mounted in a build-up substrate.

According to an exemplary embodiment of the present invention, there is provided a printed circuit board of a build-up structure in which an insulating layer and a circuit layer are stacked on a core layer, the core layer including: an electronic chip cavity in which an electronic chip is accommodated; and a dummy chip cavity in which a dummy chip is accommodated to offset warpage by the electronic chip.

The distance from the dummy chip cavity to the center of the core layer may be equal to the distance from the electronic chip cavity to the center of the core layer, and the number of the electronic chip cavity may be equal to the number of the dummy chip cavity.

The electronic chip and the dummy chip may have the same warpage value within a tolerance, and a plurality of the electronic chip cavities and a plurality of the plural dummy chip cavities may be formed in the core layer alternating one another at a regular interval.

### BRIEF DESCRIPTION OF THE DRAWINGS

FIG. 1 is a view showing a printed circuit board according to an exemplary embodiment of the present invention on which an electronic chip and a dummy chip are mounted;

FIG. 2 is a cross-sectional view showing the printed circuit board according to the exemplary embodiment of the present invention on which the electronic chip and the dummy chip are mounted; and

FIGS. 3A and 3B are a pair of graphs showing improvement in warpage value by virtue of the printed circuit board according to the exemplary embodiment of the present invention on which the dummy chip is mounted.

### DESCRIPTION OF THE PREFERRED EMBODIMENTS

Hereinafter, exemplary embodiments of the present invention will be described in detail with reference to the accompanying drawings.

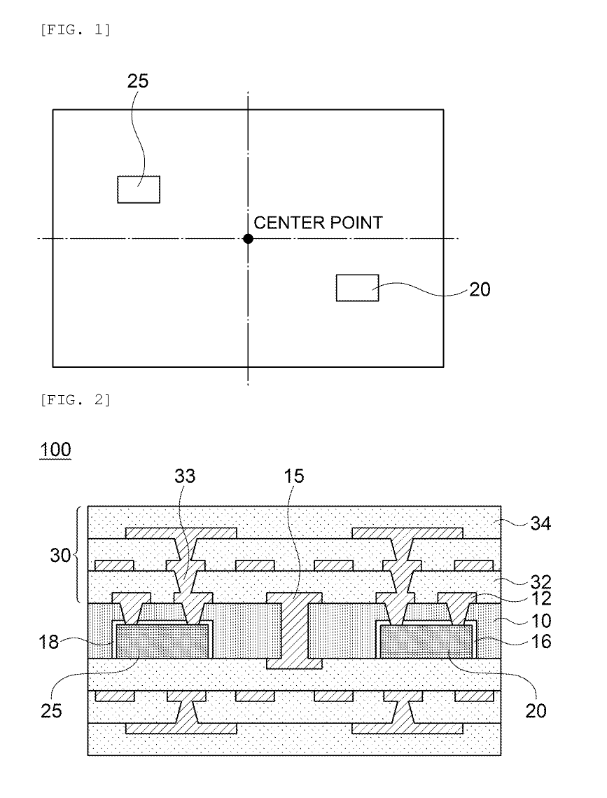

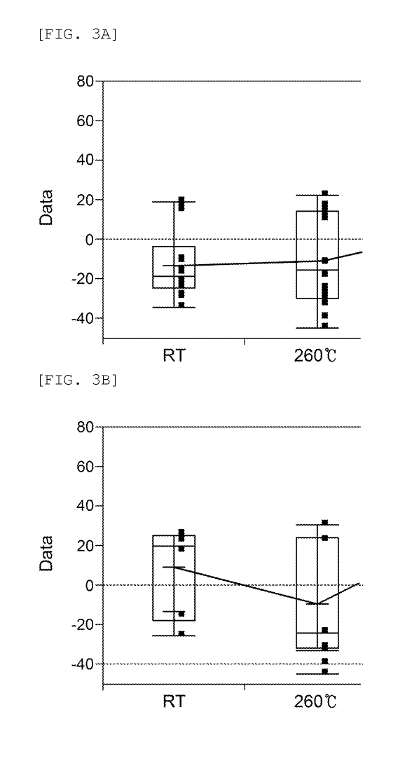

FIG. 1 is a view showing a printed circuit board according to an exemplary embodiment of the present invention on which an electronic chip and a dummy chip are mounted; FIG. 2 is a cross-sectional view showing the printed circuit board according to the exemplary embodiment of the present invention on which the electronic chip and the dummy chip are mounted; and FIGS. 3A and 3B are a pair of graphs showing improvement in warpage value by virtue of the printed circuit board according to the exemplary embodiment of the present invention on which the dummy chip is mounted.

As shown in FIGS. 1 and 2, the printed circuit board according to the exemplary embodiment of the present invention has a build-up structure in which an insulating layer and a circuit layer are stacked on a core layer. In the core layer, an electronic chip cavity and a dummy chip cavity are formed.

A core layer 10 may be formed of an insulating material such as resin and may include glass fabric so as to increase the modulus, although not shown in the drawings.

On upper and lower surfaces of the core layer 10, copper foil layers formed of copper are formed, and etching is performed thereon to form circuit patterns 12.

Here, the circuit patterns 12 formed on the upper and lower surfaces of the core layer 10 may have the same thickness. Alternatively, the lower surface of the core layer 10 may be thicker than the upper surface in order to suppress warpage of the board or depending on design considerations.

In addition, in the core layer 10, an electronic chip cavity 16 having a diameter larger than an electronic chip 20 is formed so as to accommodate the electronic chip 20. The electronic chip cavity 16 is sized to sufficiently accommodate the electronic chip 20.

At both sides of the electronic chip cavity 16, a through via 15 is formed to connect between the circuit patterns 12 formed on the upper and lower surfaces of the core layer 10. The through via 15 may have linear or sand glass shape with a predetermined width.

On the core layer 10, an insulating layer 30 may be built up. The insulating layer 30 includes multiple layers 32 stacked on one another and may include an insulating film material such as glass fabric or a build-up film in order to suppress warpage of the board due to the difference in thermal expansion coefficients.

That is, the insulating layer 30 may be glass fabric impregnated with resin in order to increase the modulus or may be formed of only an insulating film such as a build-up film without glass fabric.

Further, the insulating layer 30 may have a plurality of vias 33 for conduction between layers. The vias 33 may be largely arranged around the electronic chip 20 in order to suppress warpage of the board while enabling conduction between layers.

In another exemplary embodiment, in order to suppress warpage of the board, each of the multiple layers 32 may have different thickness. That is, the layers 32 to be built up are stacked on one another such that each of the layers 32 has different thickness taking into account its own thermal expansion coefficient. By doing so, warpage which may occur while the insulating layer 30 is formed can be suppressed.

In addition, on the uppermost layer of the insulating layer 30, a solder resist 34 may be applied in order to protect the layers 32.

Further, in the core layer 10, a dummy chip cavity 18 may be formed in order to suppress or offset warpage caused by the electronic chip 20 in the electronic chip cavity 16.

That is, the dummy chip cavity 18 may accommodate a dummy chip 25 having the same size and warpage value as the warpage of the electronic chip 20 within a tolerance so that warpage of the electronic chip 20 in the electronic cavity 16 can be offset.

Here, the electronic chip 20 accommodated in the dummy chip cavity 18 may or may not be operable.

In addition, the dummy chip cavity 18 and the electronic chip cavity 16 may have the same distance to the center of the core layer 10 so as to balance them.

If the electronic chip cavity 16, for example, is formed at the center of the core layer 10, however, it is not possible to form the dummy chip cavity 18 to offset the warpage of the electronic chip 20.

Accordingly, the dummy chip cavity 18 according to the exemplary embodiment of the present invention may be formed only when the electronic chip cavity 16 is formed having a predetermined distance from the center of the core layer 10.

Further, if a number of electronic chip cavities 16 are formed in the core layer 10, the same number of the dummy chip cavities 18 are formed, and the electronic chip cavities 16 and the dummy chip cavities 18 are alternated.

The dummy chip cavity 18 accommodating a dummy chip 25 is manufactured in the same process as that of the electronic chip cavity 16 in which the electronic chip 20 is accommodated therein and resin fills the electronic chip cavity 16. In other words, the dummy chip cavity 18 is also formed by laser when the electronic chip cavity 16 is formed, and each of the cavities is filled with the same amount of resin.

As described above, by forming the dummy chip cavity 18 and the dummy chip 25 in the core layer 10, warpage is effectively suppressed as can be seen from FIGS. 3A and 3B.

FIGS. 3A and 3B show warpage results depending on temperature. In case of (a) in which no dummy chip cavity is formed, it can be seen that the graph has a crying shape rather than a smiling shape depending on room temperature. In particular, above temperature of 260° C., unbalance in warpage becomes significant.

In case of (b) in which the dummy chip cavity 18 and the electronic chip cavity 16 are balanced, it can be seen that a crying shape warpage is suppressed and variation is improved at both high and lower temperatures.

Therefore, although the dummy chip cavity 18 and the dummy chip 25 according to the exemplary embodiment of the present invention may cause cost for manufacturing the printed circuit boar 100 to be increased, defective products due to warpage can be efficiently decreased, thereby significantly improving productivity.

According to the exemplary embodiment of the present invention, overall warpage of a printed circuit board can be offset by incorporating a dummy chip to suppress warpage by an electronic chip mounted in a build-up substrate, thereby increasing productivity.

Thus far, although the printed circuit board has been described according to the exemplary embodiment of the present invention, the present invention is not limited thereto, but may be variously modified and altered by those skilled in the art.

What is claimed is:

1. A printed circuit board of a build-up structure in which an insulating layer and a circuit layer are stacked on a core layer, the core layer comprising:
an electronic chip cavity in which an electronic chip is accommodated; and
a dummy chip cavity in which a dummy chip is accommodated to offset warpage by the electronic chip.

2. The printed circuit board according to claim 1, wherein a distance from the dummy chip cavity to a center of the core layer is equal to a distance from the electronic chip cavity to the center of the core layer.

3. The printed circuit board according to claim 1, wherein the number of the electronic chip cavity is equal to the number of the dummy chip cavity.

4. The printed circuit board according to claim 1, wherein the electronic chip and the dummy chip have the same warpage value within a tolerance.

5. The printed circuit board according to claim 1, wherein a plurality of the electronic chip cavities and a plurality of the plural dummy chip cavities are formed in the core layer alternating one another at the center of the core layer.
